(19) United States
(12) Patent Application Publication
(10) Pub. No.: US 2018/0116077 A1
(43) Pub. Date: Apr. 26, 2018

(54) ELECTRONIC DEVICE AND SHIELDING STRUCTURE THEREOF

(71) Applicant: Wistron NeWeb Corp., Hsinchu (TW)

(72) Inventors: Jen-Yung CHANG, Hsinchu (TW); Tien-Chun HUNG, Hsinchu (TW)

(21) Appl. No.: 15/628,301

(22) Filed: Jun. 20, 2017

(30) Foreign Application Priority Data
Oct. 26, 2016 (TW) 105216257

(51) Int. Cl. H05K 9/00; H05K 5/00; H05K 1/02

(52) U.S. Cl. CPC H05K 9/0024; H05K 5/0043; H05K 1/0218; H05K 9/0098; H05K 9/0081

(57) ABSTRACT

A shielding structure is provided. The shielding structure includes a frame and a cover. The frame includes at least one first frame connection portion, at least one first notch, at least one second frame connection portion and at least one second notch. The first notch is formed on a first frame edge of the frame. The second notch is formed on a second frame edge of the frame. The cover includes a cover portion, at least one first cover connection portion, at least one first cover connection portion and at least one first linking portion. The cover portion includes a first cover portion edge and a second cover portion edge. The first cover connection portion is disposed on the first cover portion edge. The first linking portion is integrally connected to the first frame edge and the first cover portion edge.

### CROSS REFERENCE TO RELATED APPLICATIONS

This Application claims priority of Taiwan Patent Application No. 105216257, filed on Oct. 26, 2016, the entirety of which is incorporated by reference herein.

### BACKGROUND OF THE INVENTION

### Field of the Invention

The present invention relates to a shielding structure, and in particular to a shielding structure shielding an electronic element.

### Description of the Related Art

Conventional shielding structures are mounted to a print circuit board by surface mount technology (SMT) to shield one or more electronic elements. However, when an electronic element shielded by the shielding structure becomes damaged, it is difficult to access the electronic element in order to repair it. Additionally, the shielding structure obstructs airflow, which reduces the welding quality of the electronic element, and also reduces the heat dissipation effect of the electronic element.

One design for conventional shielding structures has two pieces to improve the convenience of repairs. However, the two-piece shielding structure needs double the amount of raw materials (for the cover and the frame) and double the manufacturing time (the time for punching the frame, and the time for assembling the cover and the frame), and the manufacturing cost is thus increased.

### BRIEF SUMMARY OF THE INVENTION

In one embodiment, a shielding structure is provided. The shielding structure is a rotational symmetry structure and is adapted to be disposed on a circuit board to suppress electromagnetic interferences generated from an electronic element disposed on the circuit board. The shielding structure includes a frame and a cover. The frame includes at least one first frame connection portion, at least one first notch, at least one second frame connection portion and at least one second notch. The first notch is formed on a first frame edge of the frame. The second notch is formed on a second frame edge of the frame. The cover is integrally formed on the frame. The cover includes a cover portion, at least one first cover connection portion, at least one first linking portion and at least one second cover connection portion. The cover portion comprises a first cover portion edge and a second cover portion edge. The first cover connection portion is disposed on the first cover portion edge, wherein the first cover connection portion is located in the first notch and is adapted to be connected to the first frame connection portion. The first linking portion is integrally connected to the first frame edge and the first cover portion edge, wherein a first opening is formed between the first cover portion edge and the first frame edge, and is located between the first linking portion and the first cover connection portion. The second cover connection portion is disposed on the second cover portion edge, wherein the second cover connection portion is located in the second notch and is adapted to be connected to the second frame connection portion. The first cover connection portion is rotationally corresponding to the first frame connection portion, and the second cover connection portion is rotationally corresponding to the second frame connection portion.

In another embodiment, a shielding structure is provided. The shielding structure is adapted to be disposed on a circuit board to suppress electromagnetic interferences from an electronic element disposed on the circuit board. The shielding structure comprises a frame and a cover. The frame comprises at least one first frame connection portion, at least one first notch, at least one second frame connection portion and at least one second notch. The first notch is formed on a first frame edge of the frame. The second notch is formed on a second frame edge of the frame. The cover comprises a cover portion, at least one first cover connection portion and at least one second cover connection portion. The cover portion comprises a first cover portion edge and a second cover portion edge. The first cover connection portion is disposed on the first cover portion edge. The second cover connection portion is disposed on the second cover portion edge, wherein in a first state, the first cover connection portion is located in the first notch, the second cover connection portion is located in the second notch, the cover is integrally connected to the frame, and in a second state, the cover is separated from the frame and rotated to a predetermined angle to be assembled to the frame, when the cover is assembled to the frame, the first cover connection portion is connected to the first frame connection portion, and the second cover connection portion is connected to the second frame connection portion.

In another embodiment, an electronic device is provided. The electronic device includes a circuit board, an electronic element and a shielding structure. The electronic element is disposed on the circuit board and being an electromagnetic interference radiation source. The shielding structure substantially covers and is configured to suppress electromagnetic interferences generated from the electronic element on the circuit board. The shielding structure comprises a frame and a cover. The frame comprises at least one first frame connection portion, at least one first notch, at least one second frame connection portion and at least one second notch. The first notch is formed on a first frame edge of the frame. The second notch is formed on a second frame edge of the frame. The cover is integrally formed on the frame, and comprises a cover portion, at least one first cover connection portion, at least one first linking portion and at least one second cover connection portion. The cover portion comprises a first cover portion edge and a second cover portion edge. The first cover connection portion is disposed on the first cover portion edge, wherein the first cover connection portion is located in the first notch and is adapted to be connected to the first frame connection portion. The first linking portion is integrally connected to the first frame edge and the first cover portion edge, wherein a first opening is formed between the first cover portion edge and the first frame edge, and is located between the first linking portion and the first cover connection portion. The second cover connection portion is disposed on the second cover portion edge, wherein the second cover connection portion is located in the second notch and is adapted to be connected to the second frame connection portion. The first cover connection portion is rotationally corresponding to the first frame connection portion, and the second cover connection portion is rotationally corresponding to the second frame connection portion.

Utilizing the shielding structure of the embodiment of the invention, the cover can be easily detached from the frame and re-connected to the frame. Therefore, the repair process can be easily performed. Additionally, the shielding structure is integrally formed, and reduces the required material, and therefore the cost. By designing the positions and the shapes of the openings and the notches, the thermal convection requirement of the shielding structure can be satisfied.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1A shows a shielding structure of a first embodiment of the invention;

FIG. 1B shows the shielding structure of the first embodiment of the invention, wherein the cover is detached from the frame;

FIG. 1C shows the shielding structure of the first embodiment of the invention, wherein the cover is rotated to the predetermined angle;

FIG. 1D shows the shielding structure of the first embodiment of the invention, wherein the cover is re-connected to the frame;

FIG. 2A shows a shielding structure of a second embodiment of the invention;

FIG. 2B shows the shielding structure of the second embodiment of the invention, wherein the cover is detached from the frame;

FIG. 2C shows the shielding structure of the second embodiment of the invention, wherein the cover is rotated to the predetermined angle;

FIG. 2D shows the shielding structure of the second embodiment of the invention, wherein the cover is re-connected to the frame;

FIG. 3A shows a shielding structure of a third embodiment of the invention;

FIG. 3B shows the shielding structure of the third embodiment of the invention, wherein the cover is detached from the frame;

FIG. 3C shows the shielding structure of the third embodiment of the invention, wherein the cover is rotated to the predetermined angle;

FIG. 3D shows the shielding structure of the third embodiment of the invention, wherein the cover is re-connected to the frame;

FIG. 4A shows a shielding structure of a fourth embodiment of the invention;

FIG. 4B shows the shielding structure of the fourth embodiment of the invention, wherein the cover is detached from the frame;

FIG. 4C shows the shielding structure of the fourth embodiment of the invention, wherein the cover is rotated to the predetermined angle; and

FIG. 4D shows the shielding structure of the fourth embodiment of the invention, wherein the cover is re-connected to the frame.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

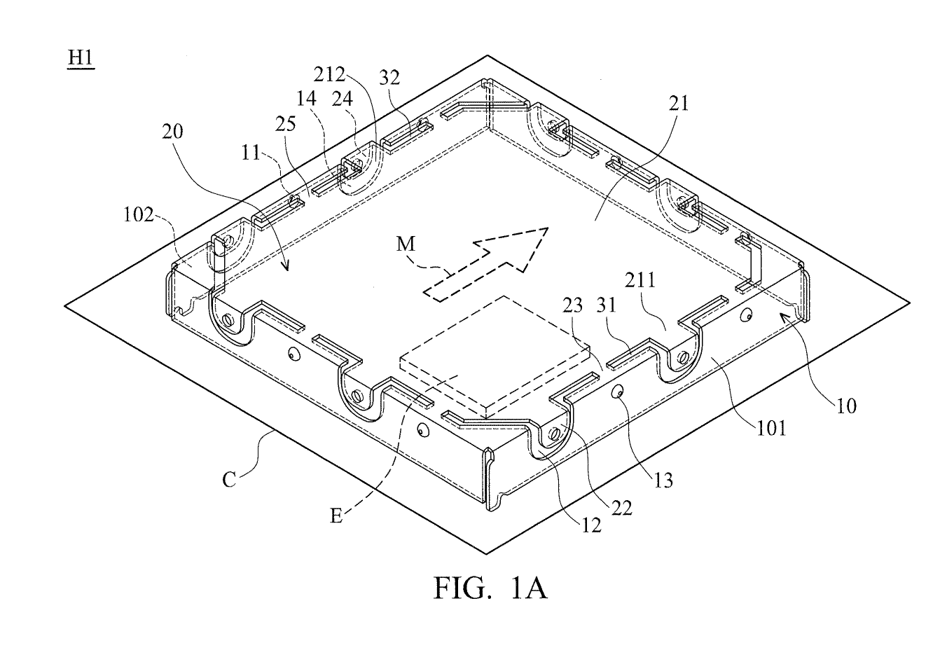

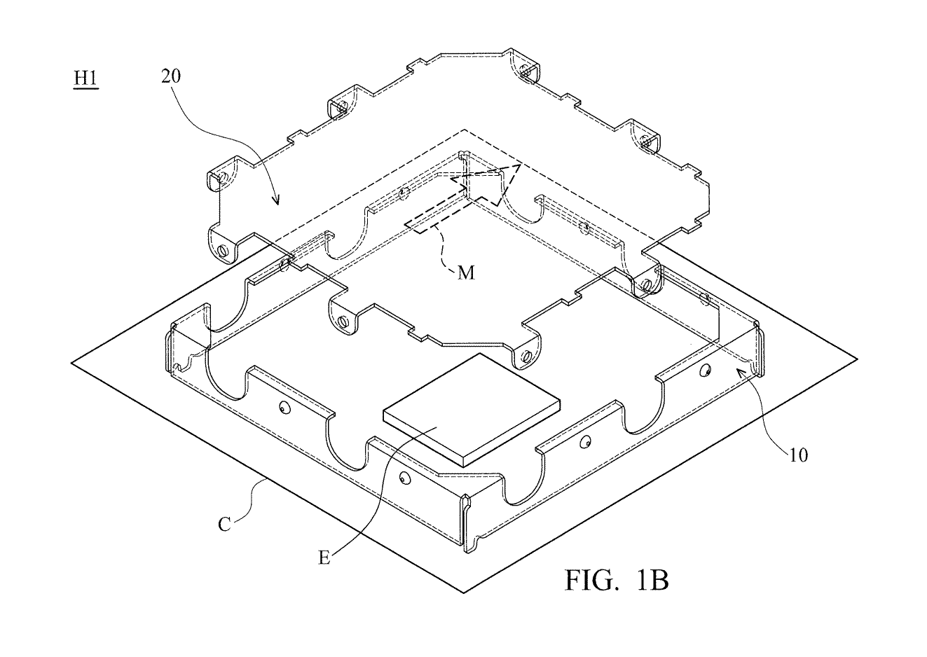

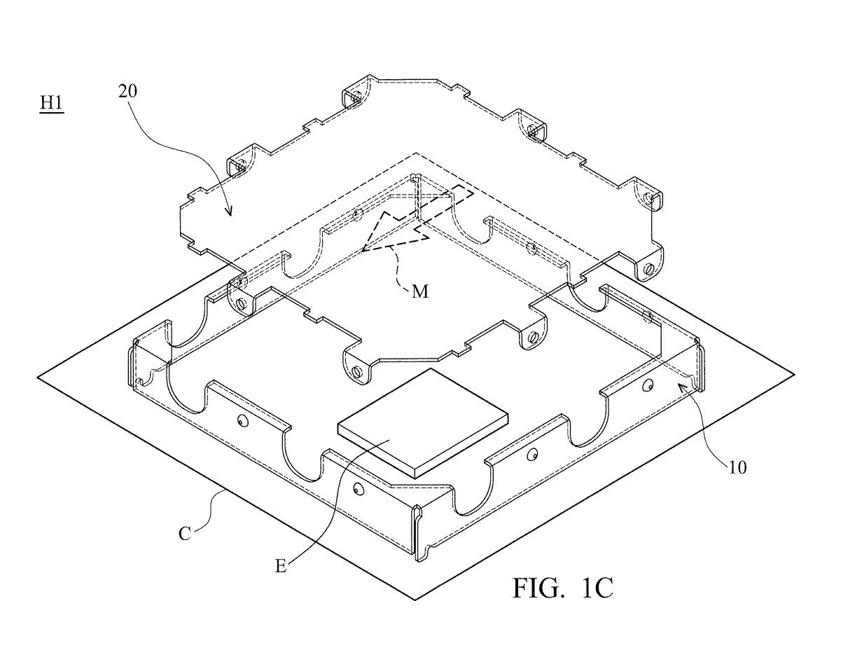

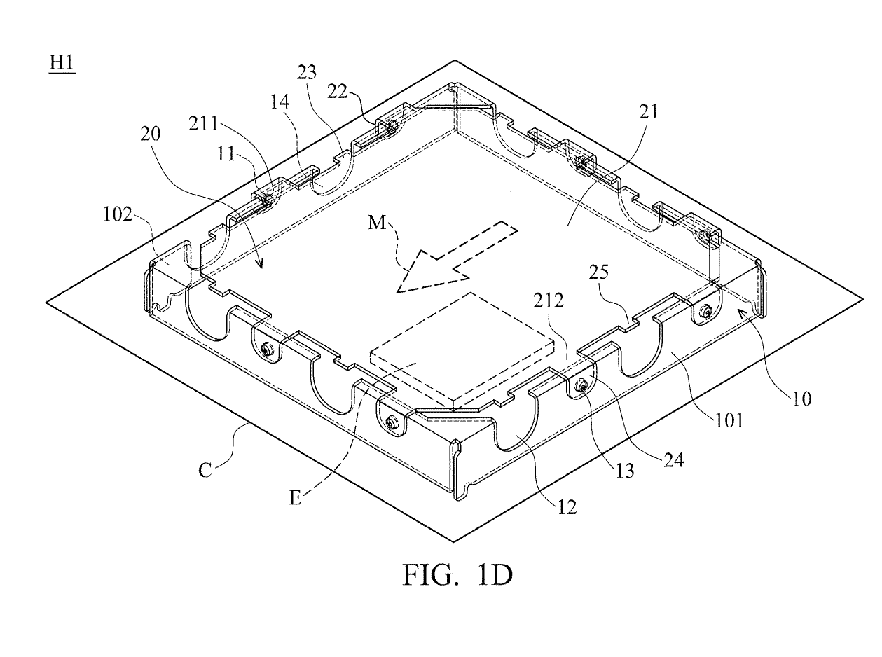

FIG. 1A shows a shielding structure H1 of a first embodiment of the invention. With reference to FIG. 1A, the shielding structure H1 is a rotational symmetric structure and is adapted to be disposed on a circuit board C to shield an electronic element E on the circuit board. The shielding structure H1 includes a frame 10 and a cover 20. The frame 10 includes at least one first frame connection portion 11, at least one first notch 12, at least one second frame connection portion 13 and at least one second notch 14. The first notch 12 is formed on a first frame edge 101 of the frame. The second notch 14 is formed on a second frame edge 102 of the frame. The cover 20 is integrally formed on the frame 10. The cover 20 includes a cover portion 21, at least one first cover connection portion 22, at least one first linking portion 23, at least one second cover connection portion 24, and at least one second linking portion 25. The cover portion 21 includes a first cover portion edge 211 and a second cover portion edge 212. The first cover connection portion 22 is disposed on the first cover portion edge 211. The first cover connection portion 22 is located in the first notch 12 and is adapted to be connected to the first frame connection portion 11. The second cover connection portion 24 is disposed on the second cover portion edge 212. The second cover connection portion 24 is located in the second notch 14 and is adapted to be connected to the second frame connection portion 13.

With reference to FIG. 1A, in a first state (in this embodiment, it is the first time the shielding structure is mounted to the circuit board), the first cover connection portion 22 is located in the first notch 12, the second cover connection portion 24 is located in the second notch 14, the cover 20 is integrally connected to the frame 10. Specifically, the first linking portion 23 is integrally connected to the first frame edge 101 and the first cover portion edge 211, wherein a first opening 31 is formed between the first cover portion edge 211 and the first frame edge 101, and is located between the first linking portion 23 and the first cover connection portion 22. The second linking portion 25 is integrally connected to the second frame edge 102 and the second cover portion edge 212, wherein a second opening 32 is formed between the second cover portion edge 212 and the second frame edge 102, and is located between the second linking portion 25 and the second cover connection portion 24.

In the first state, the shielding structure H1 is disposed on the circuit board C to shield the electronic element E, and to reduce electromagnetic interference of the electronic element E. The first opening 31 and the second opening 32 allow air flow and heat to pass therethrough. For example, in a reflow process, the heat of an outer heat source is transmitted to the electronic element E through thermal convection via the first opening 31 and the second opening 32. When the electronic element E is operated, the heat generated thereby is also removed through the first opening 31 and the second opening 32.

With reference to FIG. 1A, in one embodiment, the first opening 31 is a slot, and an extending direction of the first opening 31 is parallel to the first cover portion edge 211. The second opening 32 is a slot, and an extending direction of the second opening 32 is parallel to the second cover portion edge 121. In this embodiment, the cover portion 21 is a plate; the cover portion 21 is perpendicular to the first cover connection portion 22 and the second cover connection portion 24. The cover portion 21, the first linking portion 23 and the second linking portion 25 are located on the same plane.

When the electronic element E is damaged and needs to be replaced, the cover 20 is cut off from the frame 10, and the electronic element E can be removed and replaced with a new one. After the electronic element E is replaced, the cover 20 is re-connected to the frame 10. In this instance, referring to FIGS. 1A, 1B, 1C and ID, the cover 20 will be cut off from the frame 10, rotated to a predetermined angle, and re-connected to the frame 10. In FIG. 1A, the first cover connection portion 22 is rotationally corresponding to the first frame connection portion 11, and the second cover connection portion 24 is rotationally corresponding to the second frame connection portion 13. With reference to FIG. 1D, the first notch 12 is rotationally corresponding to the first frame connection portion 11, and the second notch 14 is rotationally corresponding to the second frame connection portion 13. In FIGS. 1A, 1B, 1C and 1D, the directional mark M indicating the directions of the cover 20 is only shown for clarifying the rotation of the cover 20 and is not meant to restrict the invention.

With reference to FIG. 1B, in a second state (in this embodiment, the state that the electronic element E is to be replaced), the first linking portion 23 and the second linking portion 25 are cut off. The cover 20 is therefore separated from the frame 10. Due to the first openings 31 on two sides of the first linking portion 23 and the second openings 32 on two sides of the second linking portion 25, the first linking portion 23 and the second linking portion 25 can be easily cut off using cutting tools. With reference to FIG. 1C, then, the cover is rotated to a predetermined angle. Next, with reference to FIG. 1D, the first cover connection portion 22 is connected to the first frame connection portion 11, and the second cover connection portion 24 is connected to the second frame connection portion 13.

With reference to FIGS. 1A, 1B, 1C and 1D, in this embodiment, the predetermined angle is 180°/N, the first frame connection portion 11 is formed on the second frame edge 102, and the second frame connection portion 13 is formed on the first frame edge 101. After the cover is rotated to the predetermined angle, the first cover portion edge 211 overlaps with the second frame edge 102, and the second cover portion edge 212 overlaps with the first frame edge 101.

By utilizing the shielding structure of the embodiment of the invention, the cover can be easily detached from the frame and re-connected to the frame. Therefore, the repair or replacement can be easily performed. Additionally, the shielding structure is integrally formed, and reduces the required material, namely the cost and the number of molds needed. By designing the positions and the shapes of the openings and the notches, the thermal convection requirement of the shielding structure can be satisfied.

In the embodiment above, the first state is the state that the shielding structure first time mounted to the circuit board, which is, commonly, the production status of the electronic device utilizing the shielding structure of the embodiments. However, the disclosure is not meant to restrict the invention, in one embodiment, the production status of the electronic device utilizing the shielding structure of the embodiments can be the second state.

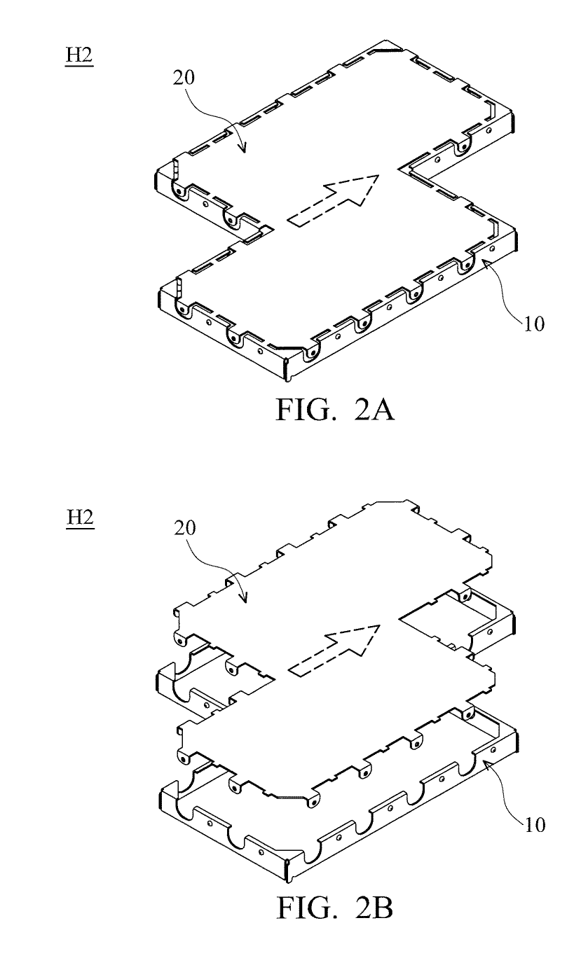

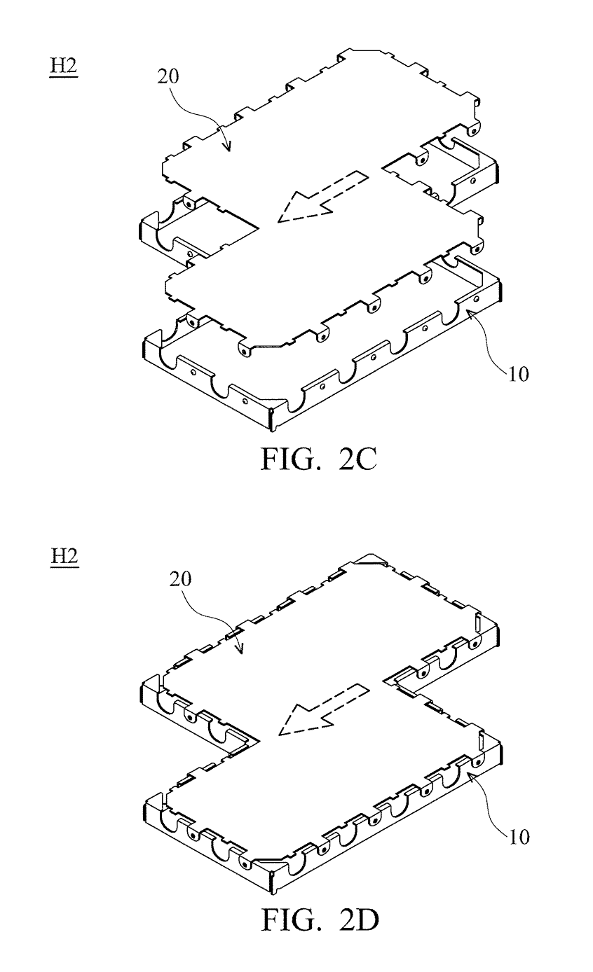

In the embodiment above, the predetermined angle is 180°. The embodiment can be utilized to the structures with equilateral polygon shapes, unilateral polygon shapes (for example, rectangular) or other rotational symmetric shapes. With reference to FIGS. 2A-2D, in this embodiment, the shielding structure H2 is a rotational symmetric structure with a stair shape. The predetermined angle of the shielding structure H2 is 1800.

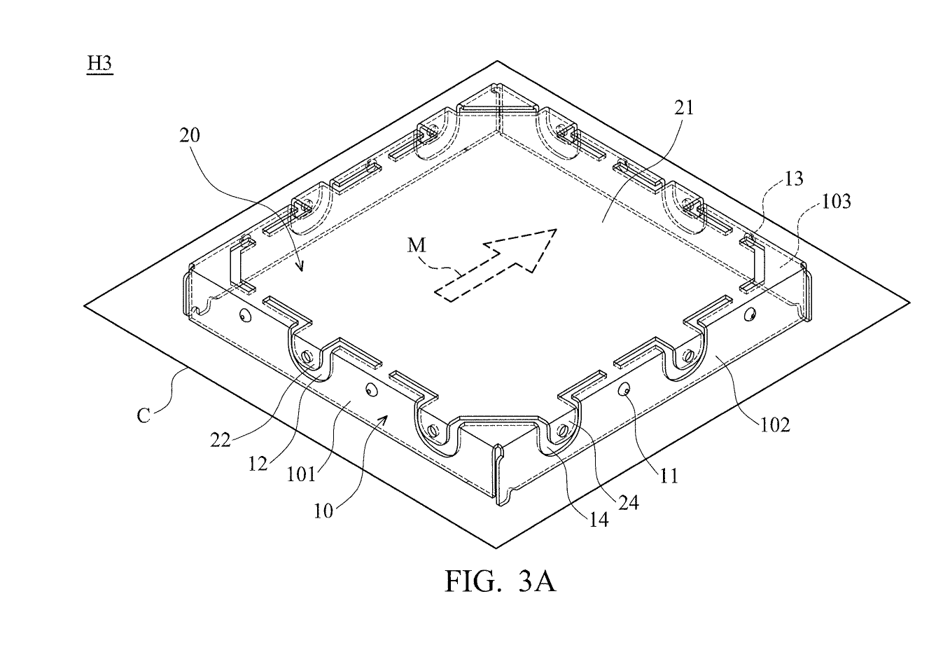

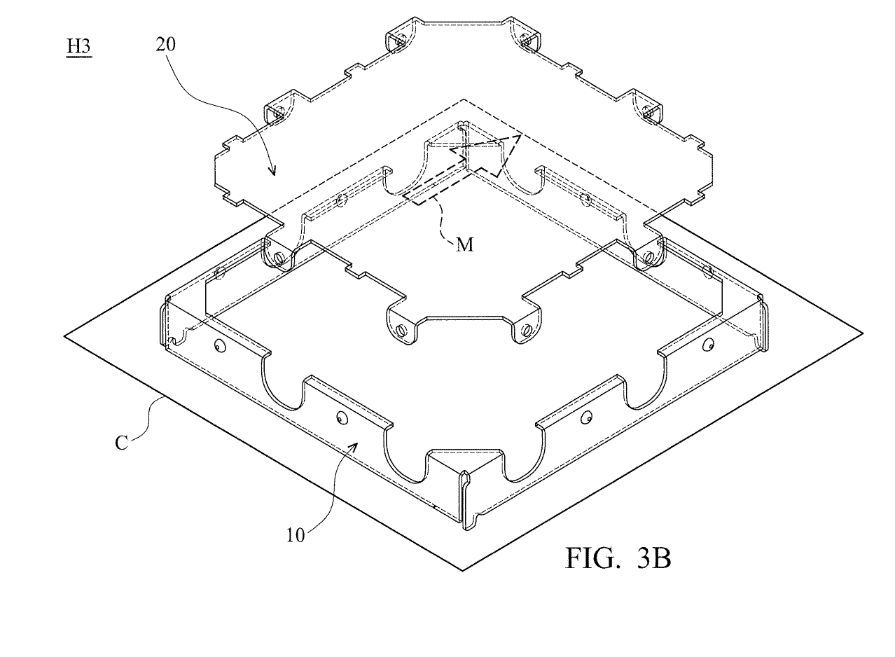

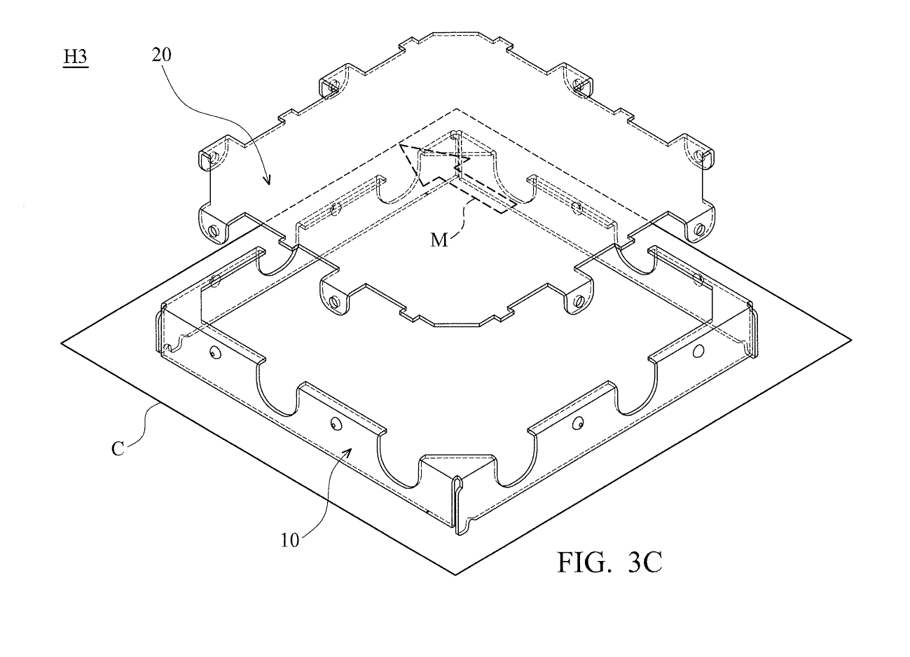

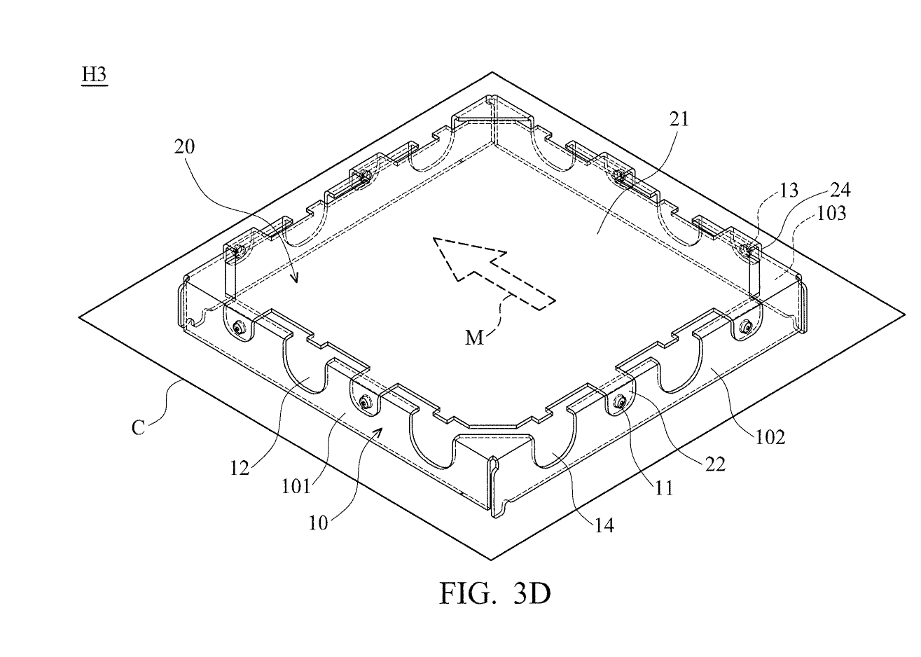

FIGS. 3A-3D show a shielding structure H3 of another embodiment of the invention, wherein the cover portion 21 is an equilateral N-gon, and the predetermined angle is 360°/N. For example, in this embodiment, the predetermined angle is 900. The first notch 12 is formed on a first frame edge 101 of the frame. The second notch 14 is formed on a second frame edge 102 of the frame. The first cover connection portion 22 is located in the first notch 12, and is adapted to be connected to the first frame connection portion 11. The second cover connection portion 24 is located in the second notch 14, and is adapted to be connected to the second frame connection portion 13. The first frame connection portion 13 is formed on the second frame edge 102, and the second frame connection portion 13 is formed on a third frame edge of the frame 103.

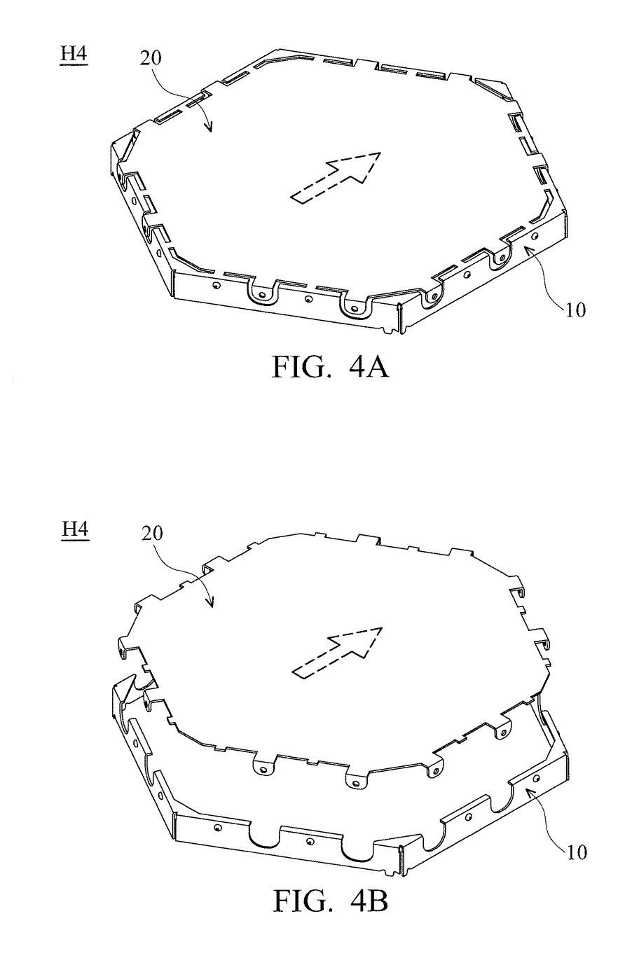

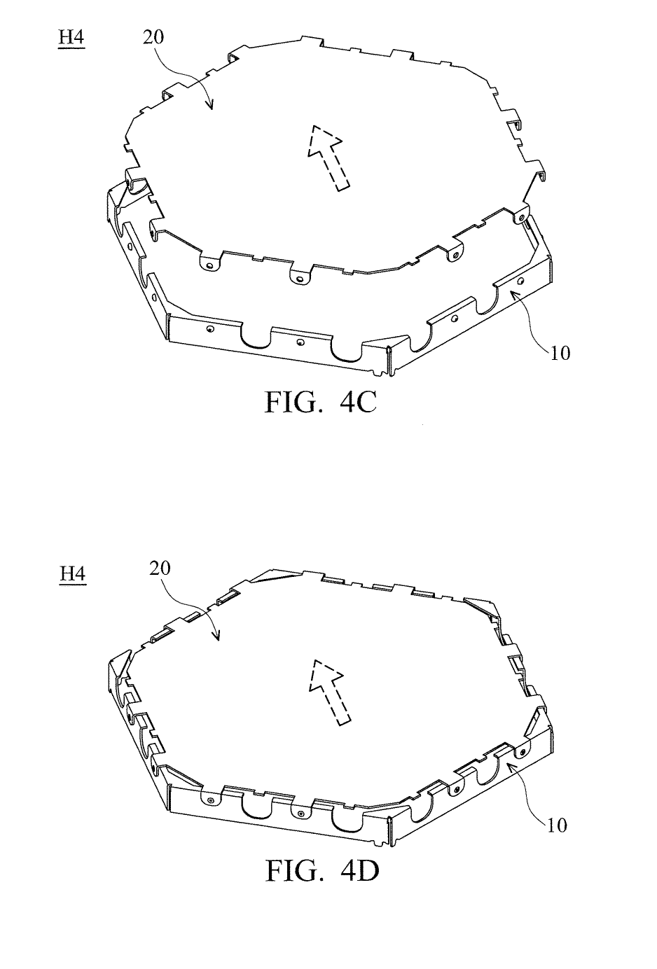

With reference to FIGS. 4A-4D, in this embodiment, the shielding structure H4 is a hexagon, and the predetermined angle is 60°. It should be noted that the shielding structure H4 can also be utilized in the embodiment such that the predetermined angle is 1800.

In the embodiments above, the cover connection portions wedge the frame connection portions. However, the disclosure is not meant to restrict the invention. The cover connection portions can be connected to the frame connection portions by buckling or other ways.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term).

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A shielding structure, which is a rotational symmetry structure and is adapted to be disposed on a circuit board to suppress electromagnetic interferences generated from an electronic element disposed on the circuit board, comprising:
a frame, comprising:
at least one first frame connection portion;
at least one first notch, formed on a first frame edge of the frame;
at least one second frame connection portion; and
at least one second notch, formed on a second frame edge of the frame; and
a cover, integrally formed on the frame, comprising:
a cover portion, comprising a first cover portion edge and a second cover portion edge;
at least one first cover connection portion, disposed on the first cover portion edge, wherein the first cover connection portion is located in the first notch and is adapted to be connected to the first frame connection portion;
at least one first linking portion, integrally connected to the first frame edge and the first cover portion edge, wherein a first opening is formed between the first cover portion edge and the first frame edge, and is located between the first linking portion and the first cover connection portion;
at least one second cover connection portion, disposed on the second cover portion edge, wherein the second cover connection portion is located in the second notch and is adapted to be connected to the second frame connection portion; and
wherein the first cover connection portion is rotationally corresponding to the first frame connection portion, and the second cover connection portion is rotationally corresponding to the second frame connection portion.

2. The shielding structure as claimed in claim 1, the cover further comprising at least one second linking portion, integrally connected to the second frame edge and the second cover portion edge, wherein a second opening is formed between the second cover portion edge and the second frame edge, and is located between the second linking portion and the second cover connection portion.

3. The shielding structure as claimed in claim 2, wherein the first opening is a slot, an extending direction of the first opening is parallel to the first cover portion edge, the second opening is a slot, and an extending direction of the second opening is parallel to the second cover portion edge.

4. The shielding structure as claimed in claim 2, wherein the cover portion is a plate, and the first cover connection portion and the second cover connection portion are extended and bended from the cover portion.

5. The shielding structure as claimed in claim 3, wherein the cover portion, the first linking portion and the second linking portion are located on the same plane.

6. The shielding structure as claimed in claim 2, wherein in a second state, the first linking portion and the second linking portion are broken, the cover is separated from the frame and rotated to a predetermined angle to be assembled to the frame, when the cover is assembled to the frame, the first cover connection portion is connected to the first frame connection portion, and the second cover connection portion is connected to the second frame connection portion.

7. The shielding structure as claimed in claim 6, wherein the cover portion is an equilateral N-gon, the predetermined angle is 360°/N, the first frame connection portion is formed on the second frame edge, and the second frame connection portion is formed on a third frame edge of the frame.

8. The shielding structure as claimed in claim 6, wherein the predetermined angle is 180°/N, the first frame connection portion is formed on the second frame edge, and the second frame connection portion is formed on the first frame edge.

9. The shielding structure as claimed in claim 8, wherein after the cover is rotated to the predetermined angle, the first cover portion edge overlaps the second frame edge, and the second cover portion edge overlaps the first frame edge.

10. A shielding structure, adapted to be disposed on a circuit board to suppress electromagnetic interferences from an electronic element disposed on the circuit board, comprising:
a frame, comprising:
at least one first frame connection portion;
at least one first notch, formed on a first frame edge of the frame;
at least one second frame connection portion; and
at least one second notch, formed on a second frame edge of the frame; and
a cover, comprising:
a cover portion, comprising a first cover portion edge and a second cover portion edge;
at least one first cover connection portion, disposed on the first cover portion edge;
at least one second cover connection portion, disposed on the second cover portion edge, wherein in a first state, the first cover connection portion is located in the first notch, the second cover connection portion is located in the second notch, the cover is integrally connected to the frame, and in a second state, the cover is separated from the frame and rotated to a predetermined angle to be assembled to the frame, when the cover is assembled to the frame, the first cover connection portion is connected to the first frame connection portion, and the second cover connection portion is connected to the second frame connection portion.

11. The shielding structure as claimed in claim 10, wherein the first opening is a slot, an extending direction of the first opening is parallel to the first cover portion edge, the second opening is a slot, and an extending direction of the second opening is parallel to the second cover portion edge.

12. The shielding structure as claimed in claim 10, wherein the cover portion is a plate, and the first cover connection portion and the second cover connection portion are extended and bended from the cover portion.

13. The shielding structure as claimed in claim 10, wherein the cover portion is an equilateral N-gon, the predetermined angle is 360°/N, the first frame connection portion is formed on the second frame edge, and the second frame connection portion is formed on a third frame edge of the frame.

14. The shielding structure as claimed in claim 10, wherein the predetermined angle is 180°/N, the first frame connection portion is formed on the second frame edge, and the second frame connection portion is formed on the first frame edge.

15. The shielding structure as claimed in claim 10, wherein after the cover is rotated to the predetermined angle, the first cover portion edge overlaps the second frame edge, and the second cover portion edge overlaps the first frame edge.

16. An electronic device, comprising:
a circuit board;
an electronic element, disposed on the circuit board and being an electromagnetic interference radiation source; and
a shielding structure, substantially covering and configured to suppress electromagnetic interferences generated from the electronic element on the circuit board, the shielding structure comprising:
a frame, comprising:
at least one first frame connection portion;
at least one first notch, formed on a first frame edge of the frame;
at least one second frame connection portion; and
at least one second notch, formed on a second frame edge of the frame; and
a cover, integrally formed on the frame, comprising:
a cover portion, comprising a first cover portion edge and a second cover portion edge;
at least one first cover connection portion, disposed on the first cover portion edge, wherein the first cover connection portion is located in the first notch and is adapted to be connected to the first frame connection portion;
at least one first linking portion, integrally connected to the first frame edge and the first cover portion edge, wherein a first opening is formed between the first cover portion edge and the first frame edge, and is located between the first linking portion and the first cover connection portion; and
at least one second cover connection portion, disposed on the second cover portion edge, wherein the second cover connection portion is located in the second notch and is adapted to be connected to the second frame connection portion,
wherein the first cover connection portion is rotationally corresponding to the first frame connection portion, and the second cover connection portion is rotationally corresponding to the second frame connection portion.

17. The shielding structure as claimed in claim 16, the cover further comprising at least one second linking portion, integrally connected to the second frame edge and the second cover portion edge, wherein a second opening is formed between the second cover portion edge and the second frame edge, and is located between the second linking portion and the second cover connection portion.

18. The shielding structure as claimed in claim 17, wherein in a second state, the first linking portion and the second linking portion are broken, the cover is separated from the frame and rotated to a predetermined angle to be assembled to the frame, when the cover is assembled to the frame, the first cover connection portion is connected to the first frame connection portion, and the second cover connection portion is connected to the second frame connection portion.

19. The shielding structure as claimed in claim 18, wherein the cover portion is an equilateral N-gon, the predetermined angle is 360°/N, the first frame connection portion is formed on the second frame edge, and the second frame connection portion is formed on a third frame edge of the frame.

20. The shielding structure as claimed in claim 17, wherein the cover portion is a plate, and the first cover connection portion and the second cover connection portion are extended and bended from the cover portion.
